(19) United States
(12) Patent Application Publication
(10) Pub. No.: US 2015/0214401 A1
(43) Pub. Date: Jul. 30, 2015

(54) ABSORBENT Cu2ZnSn(S,Se)4-BASED MATERIAL HAVING A BAND-SEPARATION GRADIENT FOR THIN-FILM PHOTOVOLTAIC APPLICATIONS

(71) Applicant: COMMISSARIAT A L'ENERGIE ATOMIQUE ET AUX ENERGIES ALTERNATIVES, Paris (FR)

(72) Inventors: Louis Grenet, Grenoble (FR); Giovanni Altamura, Saint Martin d'Heres (FR); Simon Perraud, Bandol (FR)

(73) Assignee: COMMISSARIAT A L'ENERGIE ATOMIQUE ET AUX ENERGIES ALTERNATIVES, Paris (FR)

(21) Appl. No.: 14/420,199

(22) PCT Filed: Jul. 22, 2013
(86) PCT No.: PCT/EP2013/065383

§ 371 Date: Feb. 6, 2015

(30) Foreign Application Priority Data
Aug. 10, 2012 (FR) 1257749

(51) Int. Cl. H01L 31/032; H01L 31/18; H01L 31/072

(52) U.S. Cl. CPC H01L 31/0326; H01L 31/072; H01L 31/1864; H01L 31/1828

(57) ABSTRACT

An arrangement for a stack of a photovoltaic cell comprises a first photon-absorbing layer (11) which includes sulphur (S) and selenium (Se). The first layer (11) comprises a variation, along the direction (Z) of the thickness (t) of the first layer, in the proportion of sulphur with respect to the sum of the proportions of sulphur and of selenium, the said variation being such that the first layer (11) exhibits a band-separation gradient along the direction (Z) of the thickness (t) of the first layer (11). The invention also relates to a manufacturing process and to an implemental apparatus.

### TECHNICAL FIELD OF THE INVENTION

The invention relates to an arrangement for a stack of a photovoltaic cell, comprising a first layer made of photon-absorbing material which includes sulphur S and selenium Se, this first layer comprising opposite first and second faces, the first face being intended to interact with an electrode and the second face being intended to interact with a second layer so as to form a heterojunction in combination with the first layer.

Another subject-matter of the invention is a manufacturing process and an apparatus for the manufacture of such an arrangement.

### STATE OF THE ART

Quaternary materials based on copper Cu, on tin Sn, on zinc Zn and on sulphur S and selenium Se are highly promising materials for replacing cadmium telluride or the known materials composed of an alloy of copper, of indium, of gallium, of selenium and/or of sulphur in the thin-film photovoltaic industry. The term “thin-film” is understood to mean, in the continuation of the document, that the thickness of the layer of absorbent material varies between approximately 500 nm and 10 μm. These promising materials are in particular those corresponding to the following formulae:
Cu₂ZnSnS₄, known under the name “CZTS”,
Cu₂ZnSnSe₄, known under the name “CZTSe”,
Cu₂ZnSn(S₍₁₋ₓ₎Seₓ)₄, known under the name “CZTSSe”.

This is because these absorbent materials comprise only readily available and nontoxic elements.

According to the document by H. Katagiri et al., “Enhanced Conversion Efficiencies of Cu₂ZnSnS₄— Based Thin Film Solar Cells by Using Preferential Etching Technique”, Applied Physics Express, Vol. 1, p. 041201, April 2008, the conversion efficiency of CZTS is 6.77%.

According to the document by I. L. Repins et al., “Co-evaporated Cu₂ZnSnSe₄ films and devices”, Solar Energy Materials and Solar Cells, pp. 1-6, February 2012, the conversion efficiency of CZTSe is for its part 9.15%.

Finally, according to the document by D. A. R. Barkhouse, O. Gunawan, T. Gokmen, T. K. Todorov and D. B. Mitzi, “Device characteristics of a 10.1% hydrazine-processed Cu₂ZnSn(Se,S)₄ solar cell”, Progress in Photovoltaics: Research and Applications, 2011, the conversion efficiency of CZTSSe is 10.1%.

The greatest photovoltaic conversion efficiencies in the field of thin films are obtained with the alloy of copper, indium, gallium and selenium known under the name “CIGS”. According to the document A. Gabor, J. Tuttle, M. Bode and A. Franz, “Band-gap engineering in Cu(In,Ga)Se₂ thin films grown from (In,Ga)₂Se₃ precursors”, Solar Energy Materials, Vol. 42, pp. 247-260, 1996, one of the reasons which explains such results is the production of electron forbidden bandwidth gradients in the absorbent material by virtue of the variation in the concentration of gallium and indium. These forbidden bandwidth gradients, also known as “gap gradient” or “band-separation gradient”, make possible better management of the photocreated charges in the absorbent material and limit the recombinations harmful to the conversion efficiency of the stack.

The production of an absorber having a gap gradient in CIGS is made possible by the substitution of metal atoms of the same valency between indium and gallium. In point of fact, this substitution of metal is not possible in compounds based on CZTS and CZTSe as these materials are true quaternary materials and the elements making up them have different valencies.

There exists a real need to provide a solution which makes use of an absorbent material based on sulphur and selenium which increases the current conversion efficiency of stacks and photovoltaic cells.

### Subject-Matter of the Invention

The aim of the present invention is to provide a solution in which the absorbent layer comprises selenium and sulphur and which overcomes the disadvantages mentioned above, in particular which improves the overall conversion efficiency of the stack and of the photovoltaic cell formed.

A first aspect of the invention relates to an arrangement for a stack of a photovoltaic cell, comprising a first photon-absorbing layer which includes sulphur and selenium, the said first layer comprising opposite first and second faces, the first face being intended to interact with an electrode and the second face being intended to interact with a second layer so as to form a heterojunction in combination with the first layer. Over all or a portion of its thickness delimited between the first and second faces, the first layer comprises a variation, along the direction of the thickness of the first layer, in the proportion of sulphur with respect to the sum of the proportions of sulphur and of selenium, the said variation being such that the first layer exhibits a band-separation gradient along the direction of the thickness of the first layer.

The variation in the proportion of sulphur with respect to the sum of the proportions of sulphur and of selenium can comprise a variation in the concentration of sulphur along the direction of the thickness of the first layer and/or a variation in the concentration of selenium along the direction of the thickness of the first layer.

Over all or a portion of its thickness delimited between the first and second faces, the first layer can comprise a decrease along the direction of the thickness of the first layer, from the second face and in the direction of the first face, in the ratio of the proportion of sulphur to the sum of the proportions of sulphur and of selenium.

The first layer can comprise:
over a first portion of its thickness on the side of the first face, a decrease along the direction of the thickness of the first layer, from the first face and in the direction of the second face, in the ratio of the proportion of sulphur to the sum of the proportions of sulphur and of selenium,
and, over a second portion of its thickness on the side of the second face, a decrease along the direction of the thickness of the first layer, from the second face and in the direction of the first face, in the ratio of the proportion of sulphur to the sum of the proportions of sulphur and of selenium.

Over all or a portion of its thickness delimited between the first and second faces, the first layer can comprise an increase along the direction of the thickness of the first layer, from the second face and in the direction of the first face, in the ratio of the proportion of sulphur to the sum of the proportions of sulphur and of selenium.

The material from which the first layer is formed can comprise copper, zinc and tin and can in particular be composed of the compound having the following chemical formula Cu₂ZnSn(Se₍ₓ₎S₍₁₋ₓ₎)₄.

The thickness of the first layer can be between approximately 0.5 μm and 10 μm, in particular between 0.8 μm and 1.2 μm, typically of the order of 1 μm.

A second aspect of the invention relates to a process for the manufacture of such an arrangement for a stack of a photovoltaic cell, comprising a stage of formation of the first layer carried out so that, over all or a portion of its thickness delimited between its first and second faces, the first layer comprises a variation, along the direction of the thickness of the first layer, in the proportion of sulphur with respect to the sum of the proportions of sulphur and of selenium, the said variation being such that the first layer exhibits a band-separation gradient along the direction of the thickness of the first layer.

The stage of formation of the first layer can comprise:
a stage of formation of a homogeneous layer including sulphur and/or selenium in which the proportion of sulphur is substantially constant with respect to the sum of the proportions of sulphur and of selenium along the direction of the thickness of the said homogeneous layer,
a stage of sulphurization or selenization annealing of the said homogeneous layer, carried out so as to convert the said homogeneous layer in a way resulting in a first layer comprising, over all or a portion of its thickness delimited between the first and second faces, a decrease or an increase along the direction of the thickness of the first layer, from the second face and in the direction of the first face, in the ratio of the proportion of sulphur to the sum of the proportions of sulphur and of selenium.

The stage of formation of the first layer can comprise:
a stage of formation of a homogeneous layer including sulphur and/or selenium in which the proportion of sulphur is substantially constant with respect to the sum of the proportions of sulphur and of selenium along the direction of the thickness of the said homogeneous layer,
a stage of selenization annealing of the said homogeneous layer in order to provide an intermediate layer,
a stage of sulphurization annealing of the said intermediate layer carried out so as to convert the said intermediate layer in a way resulting in a first layer comprising:
   over a first portion of its thickness on the side of the first face, a decrease along the direction of the thickness of the first layer, from the first face and in the direction of the second face, in the ratio of the proportion of sulphur to the sum of the proportions of sulphur and of selenium,
   and, over a second portion of its thickness on the side of the second face, a decrease along the direction of the thickness of the first layer, from the second face and in the direction of the first face, in the ratio of the proportion of sulphur to the sum of the proportions of sulphur and of selenium.

The stage of formation of the homogeneous layer can comprise:
a stage of deposition, by the dry route or by the liquid route, of precursors chosen from metal precursors, in particular chosen from copper and/or zinc and/or tin, and/or from sulphide precursors, in particular chosen from zinc sulphide and/or tin sulphide and/or tin disulphide and/or copper sulphide, and/or from selenide precursors, in particular chosen from zinc selenide and/or tin selenide and/or tin diselenide and/or copper selenide,
a stage of conversion of the precursors deposited in the stage of deposition carried out so as to result in the said homogeneous layer.

The stage of conversion of the precursors can comprise a stage of selenization or sulphurization annealing of the precursors deposited in the stage of deposition.

During the stage of deposition, by the dry route or by the liquid route, of the precursors, all the precursors necessary in order to obtain, on conclusion of the stage of conversion, a homogenous layer including copper and zinc and tin and sulphur and optionally selenium can be deposited, so that the stage of conversion is directly followed by a stage of selenization annealing of the homogenous layer, no stage of deposition of precursors being carried out between the stage of conversion and the stage of selenization annealing, the said stage of selenization annealing being carried out so as to obtain a first layer comprising, over all or a portion of its thickness, an increase along the direction of its thickness, from its second face and in the direction of its first face, in the ratio of the proportion of sulphur to the sum of the proportions of sulphur and of selenium.

The stage of formation of the first layer can comprise:
a stage of providing a substrate,
a stage of deposition by coevaporation, on the substrate, in a chamber in which a pressure of between approximately 10⁻⁴ mbar and 10⁻¹¹ mbar prevails, of all of the constituents of the said first layer,
the said stage of deposition by coevaporation being carried out by an adjustment over time of the rate of evaporation of each of the constituents in the chamber.

The stage of deposition by coevaporation can comprise:
a stage in which the rate of evaporation of the sulphur is decreasing over time and the rate of evaporation of the selenium is, at the same time, increasing over time,
and/or a stage in which the rates of evaporation of the sulphur and of the selenium are kept substantially constant over time,
and/or a stage in which the rate of evaporation of the sulphur is increasing over time and the rate of evaporation of the selenium is, at the same time, decreasing over time.

The stage of deposition by coevaporation can comprise a stage of adjustment of the temperature of the substrate and/or of the rates of evaporation of the constituents other than the selenium and the sulphur, as a function of the rates of evaporation of the sulphur and of the selenium, in particular in order to prevent any re-evaporation of a secondary entity.

Subsequent to the stage of deposition by coevaporation, the process can comprise a stage of annealing, under an atmosphere comprising sulphur or selenium, the layer resulting from the stage of deposition by coevaporation.

A third aspect of the invention relates to an apparatus comprising hardware and/or software components implementing the manufacturing process, comprising a conveyor capable of moving a substrate on which the first layer is formed between at least one region of sulphurization annealing, in particular providing sulphur vapour via hydrogen sulphide or by evaporation of elemental sulphur, and at least one region of selenization annealing, in particular providing selenium vapour via hydrogen selenide or by evaporation of elemental selenium.

### BRIEF DESCRIPTION OF THE DRAWINGS

Other advantages and characteristics will emerge more clearly from the description which will follow of specific embodiments of the invention given as nonlimiting examples and represented in the appended drawings, in which:

FIG. 1 is a view in cross section of an example of an arrangement for a stack of a photovoltaic cell according to the invention,

FIGS. 2 and 3 are graphs illustrating the variations in the proportion of sulphur within the first layer as a function of the height within the thickness, for different stages of a first example of a manufacturing process,

FIGS. 4 and 5 are graphs illustrating the variations in the proportion of sulphur within the first layer as a function of the height within the thickness, for different stages of a second example of a manufacturing process,

FIGS. 6 to 8 are graphs illustrating the variations in the proportion of sulphur within the first layer as a function of the height within the thickness, for different stages of a third example of a manufacturing process,

FIGS. 9 and 10 are two examples of manufacturing apparatuses according to the invention.

### DESCRIPTION OF PREFERRED FORMS OF THE INVENTION

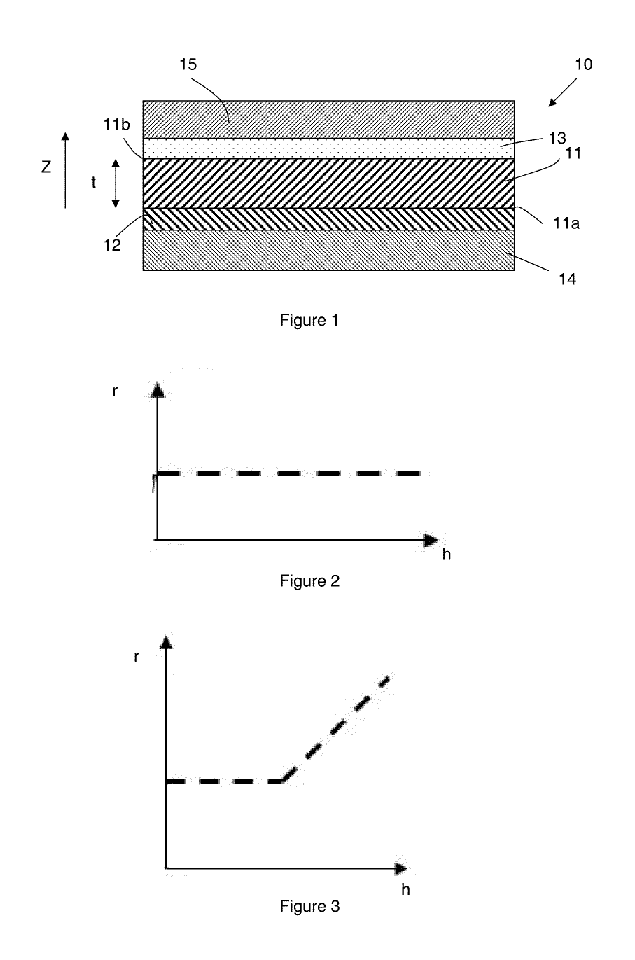

The invention described below with reference to FIGS. 1 to 10 relates to an arrangement for a stack of a photovoltaic cell (FIG. 1), to a process for the manufacture of such an arrangement and to an apparatus (FIGS. 9 and 10) which makes possible the implementation of the process. FIGS. 2 to 8 illustrate, at different stages of three manufacturing process examples, the variations (along the direction of the thickness of the first layer) in the proportion of sulphur within the first layer with respect to the sum of the proportions of sulphur and of selenium.

Thus, with reference to FIG. 1, the arrangement 10 for a stack of a photovoltaic cell comprises a first layer 11 made of a photon-absorbing material which includes sulphur S and selenium Se. The first layer 11 comprises opposite first and second faces, respectively 11a and 11b, along the direction of the stack Z, Z also being the direction of the thickness “t” of the first layer 11.

The first face 11a is intended to interact with a first electrode 12 and the second face 11b is intended to interact with a second layer 13. The interaction between the second layer 13 and the first layer 11 is such that the second layer 13 forms a heterojunction in combination with the first layer 11.

In particular but nonexclusively, the material from which the first layer 11 is formed comprises copper Cu, zinc Zn and tin Sn and is in particular composed of the compound having the following chemical formula Cu₂ZnSn(Se₍ₓ₎S₍₁₋ₓ₎)₄, also known under the name “CZTSSe”. The thickness t of the first layer 11, considered along the direction Z and between the faces 11a and 11b, is advantageously between approximately 0.5 μm and 10 μm, in particular between 0.8 μm and 1.2 μm, typically of the order of 1 μm, thus belonging to the range of thin films. However, the copper can be replaced by silver Ag or gold Au. Likewise, the tin can be replaced by germanium Ge or silicon Si or lead Pb. Finally, the zinc can be replaced by cadmium Cd or by mercury Hg.

The first electrode 12, in particular constitutive of a lower electrode along the stack direction Z, and with which the first face 11a of the first layer 11 interacts, is in particular formed from a material comprising molybdenum Mo and/or chromium Cr and/or tungsten W and/or at least one inert compound, such as gold Au and/or silver Ag. The first layer 11 is thus formed on the constituent layer of the first electrode 12, itself formed on a substrate 14, for example made of glass or of steel, optionally including molybdenum, indeed even made of bulk molybdenum.

Furthermore, the second layer 13 can be formed from a material comprising cadmium sulphide CdS and/or zinc sulphide ZnS and/or a mixture between zinc sulphide ZnS and zinc oxide ZnO. Thus, the second layer 13 is formed on the first layer 11 at its second face 11b.

The arrangement illustrated in FIG. 1 additionally comprises a second electrode 15, in particular constitutive of an upper electrode along the stack direction Z, arranged on the side opposite the first layer 11, with respect to the second layer 12. The second electrode 15 is formed from a material comprising tin-doped indium oxide ITO and/or aluminium-doped zinc oxide AZO and/or tin dioxide SnO₂ doped with fluorine. The second electrode 15 is thus composed of a layer of material formed on the second layer 13.

According to an essential characteristic, over all or a portion of its thickness t delimited between the first and second faces 11a and 11b, the first layer 11 comprises a variation, along the direction Z of the thickness t of the first layer 11, in the proportion of sulphur S with respect to the sum of the proportions of sulphur S and of selenium Se, this variation being such that the first layer 11 exhibits a band-separation gradient along the direction Z of the thickness t of the first layer 11. The band-separation gradient is also known under the name of “electron forbidden bandwidth gradient” or “gap gradient”.

In particular, the variation in the proportion of sulphur S with respect to the sum of the proportions of sulphur S and of selenium Se comprises a variation in the concentration of sulphur S along the direction Z of the thickness t of the first layer 11 and/or a variation in the concentration of selenium Se along the direction Z.

The principle of the production of a gap gradient in the absorbent material of the first layer 11 which comprises both sulphur and selenium, in particular made of CZTSSe, is based on a gradual replacement of the sulphur by selenium and vice versa within the first layer 11. Specifically, the gap energy of the Cu₂ZnSn(Se₍ₓ₎S₍₁₋ₓ₎)₄ changes from 1.5 eV to 1.0 eV when x varies from 0 to 1. By varying the rate between the local amount of sulphur and the local amount of selenium, it is thus possible to control the gap energy of the material of the layer 11.

These general principles being set down, different gap energy profiles are provided in this invention, with reference to FIGS. 3, 5 and 8, respectively. In these figures:
the abscissa “h” represents the height within the thickness t where the local analysis of the proportions of sulphur and of selenium takes place, h being counted from the first face 11a and in the direction of the second face 11b,
the ordinate “r” represents the ratio of the proportion of sulphur to the sum of the proportions of sulphur and of selenium.

With reference to FIG. 3, over all or a portion of its thickness t delimited between the first and second faces 11a, 11b, the first layer 11 can comprise a decrease along the direction Z of the thickness t of the first layer 11, from the second face 11b and in the direction of the first face 11a, in the ratio r of the proportion of sulphur S to the sum of the proportions of sulphur S and of selenium Se. In FIG. 3, this decrease in the relative proportion of sulphur is present over a portion of the thickness t of the first layer 11, approximately its half in the example represented. FIG. 2 represents the same elements (h, r) on the abscissae and ordinates but at the end of a prior stage of the manufacturing process. Such a profile, which is accompanied by a gap gradient which increases towards the second layer 13, makes it possible to increase the open circuit voltage of the cell comprising such a stack.

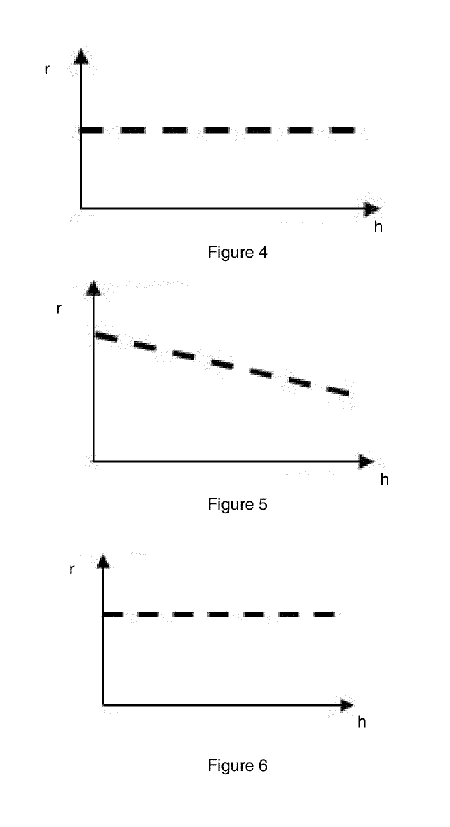

Alternatively and with reference to FIG. 5 now, over all or a portion of its thickness t delimited between the first and second faces 11a, 11b, the first layer 11 can comprise an increase along the direction Z of the thickness t of the first layer 11, from the second face 11b and in the direction of the first face 11a, in the ratio r of the proportion of sulphur S to the sum of the proportions of sulphur S and of selenium Se. In FIG. 5, this increase in the relative proportion of sulphur is present over substantially all the thickness t of the first layer 11. FIG. 4 represents the same elements (h, r) on the abscissae and ordinates but at the end of a prior stage of the manufacturing process. Such a profile, which is accompanied by a gap gradient which increases towards the back contact at the level of the first face 11a, makes it possible to repel the electrons in order in particular to limit the interface recombinations at the back contact.

With reference now to FIG. 8, the first layer 11 can alternatively comprise:
over a first portion of its thickness t on the side of the first face 11a, a decrease along the direction Z of the thickness t of the first layer 11, from the first face 11a and in the direction of the second face 11b, in the ratio r of the proportion of sulphur S to the sum of the proportions of sulphur S and of selenium Se,
and, over a second portion of its thickness t on the side of the second face 11b, a decrease along the direction Z of the thickness t of the first layer 11, from the second face 11b and in the direction of the first face 11a, in the ratio r of the proportion of sulphur S to the sum of the proportions of sulphur and of selenium Se.

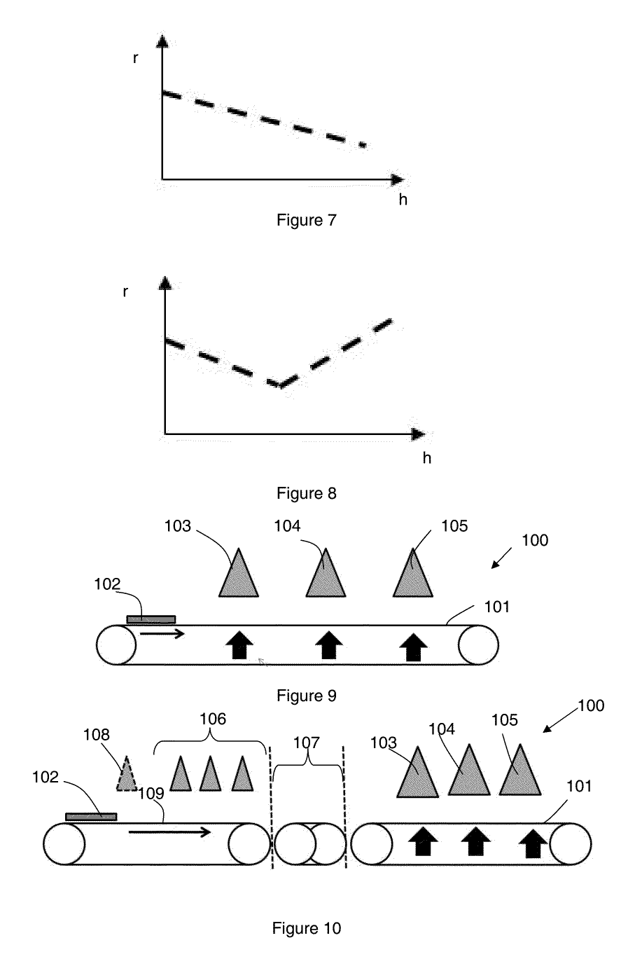

Such a profile according to FIG. 8 makes it possible to combine the effects described above with reference to FIGS. 3 and 5. FIGS. 6 and 7 represent the same elements (h, r) on the abscissae and ordinates as FIG. 8 but at the end respectively of two prior stages of the manufacturing process.

In that which precedes, the ratio of Δr to ΔZ is overall between 10% and 100% per μm of the thickness t, whether in the case of a decrease or of an increase in the ratio r.

Generally, the process for the manufacture of such an arrangement 10 comprises a stage of formation of the first layer 11 carried out so that, over all or a portion of its thickness t delimited between its first and second faces 11a, 11b, the first layer 11 comprises a variation, along the direction Z of the thickness t of the first layer 11, in the proportion of sulphur S with respect to the sum of the proportions of sulphur S and of selenium Se, this variation being such that the first layer 11 exhibits a band-separation gradient or gap gradient along the direction Z of the thickness t of the first layer 11.

Still generally, this stage of formation of the first layer 11 can be carried out either by carrying out, according to a first solution, successive selenization and/or sulphurization annealings or by employing, according to a second solution, manufacture by coevaporation.

More specifically, in order to arrive at a profile according to FIG. 3 or according to FIG. 5, the first solution provides for the stage of formation of the first layer 11 to comprise:
a stage of formation of a homogeneous layer including sulphur S and/or selenium Se in which the proportion of sulphur S is substantially constant with respect to the sum of the proportions of sulphur and of selenium Se along the direction Z of the thickness of this homogeneous layer,
and then a stage of selenization or sulphurization annealing of the homogeneous layer, carried out so as to convert or modify the homogeneous layer in a way resulting in the first layer 11 of the arrangement.

Subsequent to the stage of formation of the homogeneous layer (case of FIG. 4), carrying out a selenization annealing on the side of the second face 11b makes it possible to result in a first layer 11 corresponding to the graph of FIG. 5. On the other hand, carrying out a sulphurization annealing on the side of the second face 11b directly after the formation of the homogeneous layer (at the time when the homogeneous layer corresponds to the case of FIG. 2) makes it possible to provide a layer 11 corresponding to the graph of FIG. 3.

Alternatively, in order to arrive at a profile according to FIG. 8, the first solution provides for the stage of formation of the first layer 11 to comprise:
a stage of formation of a homogeneous layer including sulphur and/or selenium in which the proportion of sulphur S is substantially constant with respect to the sum of the proportions of sulphur S and of selenium Se along the direction Z of the thickness of the said homogeneous layer,
a stage of selenization annealing of the said homogeneous layer in order to provide an intermediate layer,
a stage of sulphurization annealing of the said intermediate layer carried out so as to convert the said intermediate layer in a way resulting in a first layer 11 according to the profile of FIG. 8.

Successively carrying out a stage of formation of the homogeneous layer (FIG. 6), then a selenization annealing (FIG. 7), followed by a sulphurization annealing, makes it possible to result in a first layer 11 corresponding to FIG. 8.

During the stage of formation of the homogeneous layer, the variability tolerance of the ratio of the proportion of sulphur to the sum of the proportions of sulphur and of selenium is typically of the order of 5%.

In order to arrive at the formation of the abovementioned homogeneous layer of CZTS or of CZTSe or of CZTSSe, it is possible to carry out a deposition, by the dry route or by the liquid route, of precursors and to then convert the deposited precursors so as to result in such a homogeneous layer. The conversion of the precursors into a homogeneous layer can in particular be carried out by employing a selenization or sulphurization annealing of the precursors deposited beforehand. The precursors can be chosen from metal precursors, in particular chosen from copper Cu and/or zinc Zn and/or tin Sn, and/or from sulphide precursors, in particular chosen from zinc sulphide ZnS and/or tin sulphide SnS and/or tin disulphide SnS₂ and/or copper sulphide Cu₂S, and/or from selenide precursors, in particular chosen from zinc selenide ZnSe and/or tin selenide SnSe and/or tin diselenide SnSe₂ and/or copper selenide Cu₂Se. Generally, it would be advantageous to select at least one precursor from the abovementioned list which comprises copper, at least one precursor from the abovementioned list which comprises tin and at least one precursor from the abovementioned list which comprises zinc.

The ratio of the proportion of sulphur to the sum of the proportions of sulphur and of selenium of the homogeneous layer CZTSSe or of CZTS or of CZTSe obtained after the first annealing (selenization or sulphurization annealing) can be adjusted between 0 and 1:
a sulphurization annealing of purely metallic precursors results in a layer of pure CZTS (without selenium),
a selenization annealing of purely metallic precursors results in a layer of pure CZTSe (without sulphur),
a sulphurization annealing of metallic and sulphide precursors

(ZnS and/or SnS and/or CuS) results in a layer of pure CZTS (without selenium),
a selenization annealing of metallic and selenide precursors (ZnSe and/or SnSe and/or CuSe) results in a layer of pure CZTSe (without selenium),
a selenization annealing of metallic and sulphide precursors (ZnS and/or SnS and/or CuS) results in a layer of CZTSSe, the ratio of the proportion of sulphur to the sum of the proportions of sulphur and of selenium of which depends on the amount of sulphur initially present,
a sulphurization annealing of metallic and selenide precursors (ZnSe and/or SnSe and/or CuSe) results in a layer of CZTSSe, the ratio of the proportion of sulphur to the sum of the proportions of sulphur and of selenium of which depends on the amount of selenium initially present.

The deposition techniques for depositing the precursors can thus be by the dry route (cathode sputtering, evaporation) or by the liquid route (plating). It is possible to vary the order of deposition of the precursors and also their sequence in order to promote the homogenization of the layer during the sulphurization or selenization phases. In particular, the sequence can be a sequence which makes it possible to result in a multilayer structure, for example a ZnS/Cu/Sn/ZnS/Cu/Sn/ . . . /Cu/Sn stack as very thin layers in order to promote the interdiffusion of the entities. By way of example, the following stack of precursors makes it possible to obtain a layer of CZTSSe of 1 μm after a selenization annealing: 340 nm of ZnS deposited by cathode sputtering, 120 nm of Cu and 160 nm of Sn deposited by electron gun evaporation.

In the specific case where the profile desired for the layer 11 is of the type of FIG. 5, it would be advantageous to provide for the deposition of all the precursors necessary in order to obtain, after the subsequent conversion of the precursors, a homogeneous layer including copper Cu and zinc Zn and tin Sn and sulphur S and optionally selenium Se. This particular deposition of all the necessary precursors will then be followed solely by a stage of conversion of the precursors into the homogeneous layer, itself directly followed by a stage of selenization annealing of the homogeneous layer. The term “directly” heretofore means that no stage of deposition of precursors is carried out between the conversion of the precursors and the selenization annealing. The stage of conversion of the precursors, carried out directly between the deposition of all the precursors and the selenization annealing, advantageously comprises a sulphurization annealing of the precursors deposited beforehand. In this scenario, this selenization annealing will thus be carried out so as to obtain a first layer 11 corresponding to the graph of FIG. 5.

In the specific case where the profile desired for the layer 11 is of the type of FIG. 8, the same stages of deposition of all the precursors, followed by a stage of conversion into a homogeneous layer (for example by sulphurization annealing), directly followed by a stage of selenization annealing, can be successively carried out in order to provide the intermediate layer, to which is subsequently applied the stage of sulphurization annealing resulting in the profile of FIG. 8. In other words, the stage of conversion, directly followed by the stage of selenization annealing, makes it possible to result in the intermediate layer, directly followed by a stage of sulphurization annealing of the intermediate layer. The term “directly” heretofore means that no stage of deposition of precursors is carried out between the stage of selenization annealing applied to the homogeneous layer and the stage of sulphurization annealing applied to the intermediate layer so as to obtain a first layer (11) of the type of FIG. 8.

In the specific case where the profile desired for the layer 11 is of the type of FIG. 3, the same stages of deposition of all the precursors, followed by a stage of conversion into a homogeneous layer, directly followed (without another stage of deposition) by a stage of sulphurization annealing, can be successively employed in order to provide the first layer 11 corresponding to the profile of FIG. 3.

It emerges from the above that a possible manufacturing process for arriving at a first layer 11 exhibiting the characteristics of FIG. 3 consists of the use of two successive annealings, the first being a selenization or sulphurization annealing of the precursors which makes it possible to obtain a homogeneous CZTSSe layer with a ratio of the proportion of sulphur to the sum of the proportions of sulphur and of selenium which is between 0 and 0.9 and which is constant along Z in the thickness t of the first layer 11. This results in the situation of FIG. 2. The second annealing is then a sulphurization annealing, which makes it possible, starting from the second face 11b which is a free face, to replace selenium atoms by sulphur atoms and to thus obtain a composition profile such that the ratio of the proportion of sulphur to the sum of the proportions of sulphur and of selenium increases on approaching the second face 11b.

It also emerges from the above that a possible manufacturing process for arriving at a first layer 11 exhibiting the characteristics of FIG. 5 consists of the use of two successive annealings, the first being a selenization or sulphurization annealing of the precursors which makes it possible to obtain a homogeneous CZTSSe layer with a ratio of the proportion of sulphur to the sum of the proportions of sulphur and of selenium which is greater (between 0.1 and 1) and constant along Z in the thickness t of the first layer 11. This results in the situation of FIG. 4. The second annealing is then a selenization annealing, which makes it possible, starting from the second face 11b which is a free face, to replace sulphur atoms by selenium atoms and to thus obtain a composition profile such that the ratio of the proportion of sulphur to the sum of the proportions of sulphur and of selenium increases on approaching the first face 11a.

Finally, it emerges from the above that a possible manufacturing process for arriving at a first layer 11 exhibiting the characteristics of FIG. 8 consists of the use of three successive annealings, the first being a selenization or sulphurization annealing of the precursors deposited which makes it possible to obtain a homogeneous CZTSSe layer with a ratio of the proportion of sulphur to the sum of the proportions of sulphur and of selenium which is between 0.1 and 1 and constant along Z in the thickness t of the first layer 11. This results in the situation of FIG. 6. The second annealing is then a selenization annealing, which makes it possible, starting from the second face 11b which is a free face, to replace sulphur atoms by selenium atoms and to thus obtain a composition profile according to FIG. 7 such that the ratio of the proportion of sulphur to the sum of the proportions of sulphur and of selenium increases on approaching the first face 11a. This is the intermediate layer mentioned above. This makes it possible to increase the content of selenium in the layer and thus to reduce the gap energy on approaching the second face 11b. The third annealing is then a sulphurization annealing which makes it possible to again increase the ratio of the proportion of sulphur to the sum of the proportions of sulphur and of selenium on approaching the second face 11b over a portion only of the thickness t on the side of the second face 11b, in order to finally arrive at the first layer 11 according to the configuration of FIG. 8.

In order to adjust the slope of the increasing and decreasing portions of the curves in FIGS. 3, 5, 7 and 8, it is possible to vary the thermal profiles of the annealings. Thus:
a short annealing (a rapid incline, followed by a short plateau (from 1 second to 10 minutes)) at high temperature (approximately 500° C.) promotes a strong gradient (a strong slope) over a short distance,
a short annealing (a rapid incline, followed by a short plateau (from 1 second to 10 minutes)) at low temperature (of between 200° C. and 400° C.) promotes a slight gradient (a slight slope) over a short distance,
a long annealing (a slow incline and/or a long plateau (from a few minutes to a few hours)) at high temperature (approximately 500° C.) promotes a slight gradient (a slight slope) over a long distance,
a long annealing (a slow incline and/or a long plateau (from a few minutes to a few hours)) at low temperature (of between 200° C. and 400° C.) promotes a slight gradient (a slight slope) over a long distance.

A sulphurization annealing thus makes it possible to convert a stack of precursors into a homogeneous CZTSSe layer and/or to gradually increase the content or the proportion of sulphur in a CZTSSe layer on approaching the second face 11b. This increase takes place by the replacement of the selenium atoms in the layer by sulphur atoms. The principle of a sulphurization annealing is to heat the layer to be sulphurized under a controlled atmosphere of sulphur. The atmosphere is composed of an inert gas (Ar, N₂) in which sulphur vapours are incorporated. These vapours can originate from the evaporation of elemental sulphur or from H₂S, in particular according to a content of between 1% and 25%, typically 5%.

By way of example, in order to obtain a CZTS layer from a ZnS/Cu/Sn stack described above, it is possible to use an annealing at 520° C. for 30 min (with a rise incline of 1° C./min) under a pressure of 600 mbar of nitrogen and a partial sulphur pressure provided by an elemental sulphur target heated to 200° C.

Generally, the parameters of a sulphurization annealing can be as follows:
a pressure of between 10⁻¹ mbar and 10 atm, preferably approximately 1 atmosphere,
a temperature of between 300° C. and 1000° C., preferably between 450° C. and 650° C.,
an annealing time of between 10 s and 180 min,
a sulphur temperature between 115° C. and 500° C.,
a temperature rise incline of the layer of between 0.1° C./min and 10° C./second, preferably between 10° C./min and 10° C./second.

A selenization annealing thus makes it possible to convert a stack of precursors into a homogeneous CZTSSe layer and/or to gradually increase the content or the proportion of selenium in a CZTSSe layer on approaching the second face 11b. This increase takes place by the replacement of the sulphur atoms in the layer by selenium atoms. The principle of a selenization annealing is to heat, under a controlled atmosphere of selenium, the layer where the proportion of selenium has to increase. The atmosphere is composed of an inert gas (Ar, N₂) in which selenium vapours are incorporated. These vapours can originate from the evaporation of elemental selenium or from H₂Se.

By way of example, in order to obtain a CZTSSe layer from a ZnS/Cu/Sn stack described above, it is possible to use an annealing at 570° C. for 30 min (with a rise incline of 10° C./min) under a pressure of 1 bar of nitrogen and a partial selenium pressure given by a weight of 2×10⁻⁴ g of selenium placed beside the sample.

Generally, the parameters of a selenization annealing can be as follows:
a pressure of between 10⁻¹ mbar and 10 atm, preferably approximately 1 atmosphere,
a temperature of between 300° C. and 1000° C., preferably between 450° C. and 650° C.,
an annealing time of between 1 s and 180 min,
a selenium temperature of between 115° C. and 500° C.,
a temperature rise incline of the layer of between 0.1° C./min and 10° C./second, preferably between 10° C./min and 10° C./second.

Any other alternative method for obtaining a homogeneous CZTSSe layer can, however, be used, for example by synthesis.

The second manufacturing solution, that is to say by means of the use of coevaporation, provides, on the other hand, for the stage of formation of the first layer 11 to comprise the provision of a substrate and then a deposition on this substrate, by coevaporation, of all the constituents of the first layer 11.

This deposition by coevaporation under ultrahigh vacuum can be carried out inside a chamber (or stand) in which a pressure of between approximately 10⁻⁴ mbar and 10⁻¹¹ mbar prevails, the rate of evaporation of each of the constituents in the chamber being adjusted over time. With regard to these principles, the stage of deposition by coevaporation can comprise in particular:
a first stage in which the rate of evaporation of the sulphur is decreasing over time and the rate of evaporation of the selenium is, at the same time, increasing over time,
and/or a second stage in which the rates of evaporation of the sulphur and of the selenium are kept substantially constant over time,
and/or a third stage in which the rate of evaporation of the sulphur is increasing over time and the rate of evaporation of the selenium is, at the same time, decreasing over time.

The successive implementation of the second and third stages makes it possible to obtain a first layer 11 corresponding to the graph of FIG. 3. The successive implementation of the first and second stages makes it possible to arrive at a first layer 11 corresponding, on the other hand, to the graph of FIG. 5. Finally, the implementation of the first and third stages makes it possible to provide a first layer 11 corresponding to the graph of FIG. 8. In the latter scenario, the second stage is optional and can optionally be inserted between the first and third stages.

By way of example, the substrate can be made of glass or of steel with optionally molybdenum, indeed even bulk molybdenum, or alternatively any other type of substrate which makes it possible to form a back contact in a growth stand. The stand, corresponding to the chamber, is pumped out to give a high vacuum, typically at a pressure of the order of 10⁻⁷ mbar, in all cases of between approximately 10⁻⁴ mbar and 10⁻¹¹ mbar. This stand comprises a substrate holder having the possibility of adjusting the temperature of the sample to set temperature values of between 0° C. and 800° C. The stand comprises at least five evaporation crucibles (for example thermal cells of Knudsen type or thermal cells heated by an electron gun) respectively for copper Cu, zinc Zn, tin Sn, sulphur S and selenium Se. The sulphur S crucible can be a conventional cell or a cell of cracker type.

It should be specified that this stage of deposition by coevaporation can comprise a stage of adjustment of the temperature of the substrate and/or of the rates of evaporation of the constituents other than the selenium and the sulphur, as a function of the rates of evaporation of the sulphur and of the selenium, in particular in order to prevent any reevaporation of the secondary entity. This adjustment stage will thus be carried out during the first stage and/or the second stage and/or the third stage which are mentioned above.

By way of example, for the management of a stream rich in selenium at the end of the first stage, during the second stage and at the start of the third stage, the following parameters can be envisaged:
stream of selenium Se adjusted to between 0.1 nm/s and 2 nm/s, in particular of the order of 0.7 nm/s,
stream of sulphur S adjusted to between 0 nm/s and 1 nm/s, in particular of the order of 0.1 nm/s,
stream of tin Sn adjusted to between 0.05 nm/s and 1 nm/s, in particular of the order of 0.45 nm/s,
stream of copper Cu adjusted to between 0 nm/s and 1 nm/s, in particular of the order of 0.2 nm/s,
stream of zinc Zn adjusted to between 0.05 nm/s and 1 nm/s, in particular of the order of 0.25 A/s,
temperature of the substrate maintained between 300° C. and 700° C., in particular of the order of 500° C.

Still by way of example, for the management of a stream rich in sulphur at the end of the first stage, during the second stage and at the start of the third stage, the following parameters can be envisaged:
stream of selenium Se adjusted to between 0 nm/s and 1 nm/s, in particular of the order of 0.1 nm/s,
stream of sulphur S adjusted to between 0.1 nm/s and 2 nm/s, in particular of the order of 0.7 nm/s,
stream of tin Sn adjusted to between 0.05 nm/s and 1 nm/s, in particular of the order of 0.45 nm/s,
stream of copper Cu adjusted to between 0 nm/s and 1 nm/s, in particular of the order of 0.2 nm/s,
stream of zinc Zn adjusted to between 0.05 nm/s and 1 nm/s, in particular of the order of 0.25 nm/s,
temperature of the substrate maintained between 100° C. and 700° C., in particular of the order of 300° C.

Finally, the coevaporation stage can be parameterized so as to provide either the homogeneous layer of CZTS or of CZTSe or of CZTSSe, or directly the first layer 11 having a gap gradient. Subsequent to the stage of deposition by coevaporation, in particular in the case where the coevaporation is not used to result in the first layer 11 finally desired, the process can comprise a stage of annealing, under an atmosphere comprising sulphur or selenium, the layer resulting from the stage of deposition by coevaporation. This is because it is obvious that a coevaporation stage can also be appropriately carried out in order to arrive at the formation not of the first layer 11 but of the homogeneous layer described above, replacing the stages of deposition of precursors and of conversion of the deposited precursors.

Two examples of apparatuses 100 which make possible the implementation of the processes of manufacture by annealings are respectively illustrated in FIGS. 9 and 10. In both cases, the apparatus 100 will comprise hardware and/or software components implementing the manufacturing process. The apparatus 100 of FIG. 9 makes it possible to produce a first layer 11 exhibiting the variation, along the direction Z of the thickness t of the first layer 11, in the proportion of sulphur with respect to the sum of the proportions of sulphur and of selenium, starting from a homogeneous layer of CZTSSe or from a layer of deposited precursors. The apparatus 100 of FIG. 10 makes it possible to produce the entire absorbent layer starting from a relatively inexpensive substrate.

With reference to FIG. 9, the apparatus 100 comprises a conveyor 101 capable of moving a substrate 102 carrying selenium and sulphur (for example carrying a homogeneous CZTSSe layer) on which the first layer 11 has to be formed between:
at least one region of sulphurization annealing 103, 105, in particular which heats the substrate (lamp, resistance, and the like), and which provides sulphur vapour via hydrogen sulphide H₂S or by evaporation of elemental sulphur produced by heating (lamp, resistance, and the like),
and at least one region of selenization annealing 104, in particular which heats the substrate (lamp, resistance, and the like) and which provides selenium vapour via hydrogen selenide H₂Se or by evaporation of elemental selenium produced by heating (lamp, resistance, and the like).

The conveyor 101 can be planned, for example, to move the substrate 102 and its homogeneous layer of CZTSSe towards the region of sulphurization annealing 103, and towards the region of selenization annealing 104 in a to movement, before potentially returning to the same region of sulphurization annealing 103 in a fro movement. However, the solution represented in FIG. 9 provides for the conveyor 101 to move the substrate 102 towards a first region of sulphurization annealing consisting of the region 103, then towards a region of selenization annealing consisting of the region 104 and then towards a second region of sulphurization annealing 105 different from the region 103. The movement of the conveyor 101 is, in this case, unidirectional.

In FIG. 9, the substrate 102 which carries a homogeneous layer of CZTSSe can pass, by virtue of the conveyor 101:
in front of the sulphurization region 105: the first layer 11 will correspond to the graph of FIG. 3,
in front of the selenization region 104: the first layer 11 will correspond to the graph of FIG. 5,
in front of the selenization region 104 and then in front of the sulphurization region 105: the first layer 11 will correspond to the graph of FIG. 8.

In FIG. 9, the substrate 102, which no longer carries a homogeneous layer but a layer of precursors, can pass, by virtue of the conveyor 101, successively:
in front of the selenization region 104 and then in front of the sulphurization region 105: the first layer 11 will correspond to the graph of FIG. 3,
in front of the sulphurization region 103 and then in front of the selenization region 104: the first layer 11 will correspond to the graph of

FIG. 5,
in front of the sulphurization region 103, then in front of the selenization region 104 and then in front of the sulphurization region 105: the first layer 11 will correspond to the graph of FIG. 8.

In the alternative form of FIG. 10, the apparatus 100 comprises, on the one hand, a region 106 for deposition of precursors necessary for the formation of the first layer 11 of the arrangement and, on the other hand, a pressurization lock 107 inserted between the region 106 for deposition of precursors and the region of sulphurization annealing 103 and/or the region of selenization annealing 104. The deposition region 106 is located upstream of the region of sulphurization annealing 103 and of the region of selenization annealing 104 along the direction of movement of the substrate 102. The apparatus 100 can also comprise a region 108 for deposition of molybdenum on the substrate 102, located upstream of the region 106 for deposition of the precursors. The movement of the substrate 102 along the regions 106 and 108 can be carried out by a conveyor 109 or via the same conveyor 101 as along the regions 103 to 105.

Finally, the apparatus 100 can comprise a control unit (not represented) which reads a data recording medium on which is recorded a computer program which comprises computer program code means for implementing the stages of the manufacturing process.

1. Arrangement for a stack of a photovoltaic cell, comprising:
a first photon-absorbing layer which includes sulphur and selenium, the first layer comprising opposite first and second faces, the first face being intended to interact with an electrode and the second face being intended to interact with a second layer so as to form a heterojunction in combination with the first layer,
wherein, over all or a portion of a thickness of the first layer delimited between the first and second faces, the first layer comprises a variation, along a direction of the thickness of the first layer, in a proportion of sulphur with respect to a sum of proportions of sulphur and of selenium, the variation being such that the first layer exhibits a band-separation gradient along the direction of the thickness of the first layer.

2. Arrangement according to claim 1, wherein the variation in the proportion of sulphur with respect to the sum of the proportions of sulphur and of selenium comprises at least one of (i) a variation in a concentration of sulphur along the direction of the thickness of the first layer and (ii) a variation in the concentration of selenium along the direction of the thickness of the first layer.

3. Arrangement according to claim 1, wherein, over all or a portion of the thickness of the first layer delimited between the first and second faces, the first layer comprises a decrease along the direction of the thickness of the first layer, from the second face and in a direction of the first face, in a ratio of the proportion of sulphur to the sum of the proportions of sulphur and of selenium.

4. Arrangement according to claim 3, wherein the first layer comprises:
over a first portion of the thickness of the first layer on a side of the first face, a decrease along the direction of the thickness of the first layer, from the first face and in the direction of the second face, in the ratio of the proportion of sulphur to the sum of the proportions of sulphur and of selenium,
and, over a second portion of the thickness of the first layer on a side of the second face, a decrease along the direction of the thickness of the first layer, from the second face and in the direction of the first face, in the ratio of the proportion of sulphur to the sum of the proportions of sulphur and of selenium.

5. Arrangement according to claim 1, wherein, over all or a portion of the thickness of the first layer delimited between the first and second faces, the first layer comprises an increase along the direction of the thickness of the first layer, from the second face and in the direction of the first face, in a ratio of the proportion of sulphur to the sum of the proportions of sulphur and of selenium.

6. Arrangement according to claim 1, wherein a material from which the first layer is formed comprises copper, zinc and tin.

7. Arrangement according to claim 1, wherein the thickness of the first layer is between approximately 0.5 μm and 10 μm.

8. Manufacturing process of an arrangement for a stack of a photovoltaic cell according to claim 1, comprising:
forming a first layer so that, over all or a portion of a thickness of the first layer delimited between opposite first and second faces, the first layer comprises a variation, along a direction of a thickness of the first layer, in a proportion of sulphur with respect to a sum of proportions of sulphur and of selenium, the variation being such that the first layer exhibits a band-separation gradient along the direction of the thickness of the first layer.

9. Manufacturing process according to claim 8, wherein the formation of the first layer comprises:
forming a homogeneous layer including at least one of sulphur and selenium wherein the proportion of sulphur is substantially constant with respect to the sum of the proportions of sulphur and of selenium along the direction of the thickness of the homogeneous layer,
sulphurization or selenization annealing the homogeneous layer, so as to convert the homogeneous layer in a way resulting in the first layer comprising, over all or a portion of the thickness delimited between the first and second faces, a decrease or an increase along the direction of the thickness of the first layer, from the second face and in a direction of the first face, in a ratio of the proportion of sulphur to the sum of the proportions of sulphur and of selenium.

10. Manufacturing process according to claim 8, wherein the formation of the first layer comprises:
forming a homogeneous layer including at least one of sulphur and selenium wherein the proportion of sulphur is substantially constant with respect to the sum of the proportions of sulphur and of selenium along the direction of the thickness of the homogeneous layer,
selenization annealing the homogeneous layer in order to provide an intermediate layer,
sulphurization annealing the intermediate layer so as to convert the intermediate layer in a way resulting in the first layer comprising:
over a first portion of the thickness on a side of the first face, a decrease along the direction of the thickness of the first layer, from the first face and in a direction of the second face, in a ratio of the proportion of sulphur to the sum of the proportions of sulphur and of selenium,
and, over a second portion of the thickness on a side of the second face, a decrease along the direction of the thickness of the first layer, from the second face and in a direction of the first face, in the ratio of the proportion of sulphur to the sum of the proportions of sulphur and of selenium.

11. Manufacturing process according to claim 9, wherein the formation of the homogeneous layer comprises:
depositing, by dry route or by liquid route, precursors chosen from metal precursors, sulphide precursors, and selenide precursors,
converting the deposited precursors so as to result in the homogeneous layer.

12. Manufacturing process according to claim 11, wherein the conversion of the precursors comprises selenizing or sulphurizing the deposited precursors.

13. Manufacturing process according to claim 11, wherein:
during deposition, by the dry route or by the liquid route, of the precursors, all the precursors necessary in order to obtain, on conclusion of the conversion, the homogeneous layer including copper and zinc and tin and sulphur are deposited,
the conversion is directly followed by selenization annealing of the homogeneous layer, no stage of deposition of precursors being carried out between the conversion and the selenization annealing, the stage of selenization annealing being carried out so as to obtain the first layer comprising, over all or a portion of the thickness of the first layer, an increase along the direction of thickness of the first layer, from the second face and in the direction of the first face, in the ratio of the proportion of sulphur to the sum of the proportions of sulphur and of selenium.

14. Manufacturing process according to claim 8, wherein the formation of the first layer comprises:
providing a substrate,
depositing by coevaporation, on the substrate, in a chamber in which a pressure of between approximately 10⁻⁴ mbar and 10⁻¹¹ mbar prevails, all constituents of the first layer,
carrying out the deposition by coevaporation by an adjustment over time of a rate of evaporation of each of the constituents in the chamber.

15. Manufacturing process according to claim 14, wherein the deposition by coevaporation comprises at least one of:
a stage in which a rate of evaporation of the sulphur is decreasing over time and a rate of evaporation of the selenium is, at a same time, increasing over time,
a stage in which rates of evaporation of the sulphur and of the selenium are kept substantially constant over time,
a stage in which a rate of evaporation of the sulphur is increasing over time and a rate of evaporation of the selenium is, at a same time, decreasing over time.

16. Manufacturing process according to claim 15, wherein
the deposition by coevaporation comprises adjusting at least one of (i) a temperature of the substrate and (ii) rates of evaporation of the constituents other than the selenium and the sulphur, as a function of the rates of evaporation of the sulphur and of the selenium.

17. Manufacturing process according to claim 15, wherein, subsequent to the deposition by coevaporation, the process comprises annealing, under an atmosphere comprising sulphur or selenium, the layer resulting from the deposition by coevaporation.

18. Apparatus comprising:
hardware and/or software components implementing the manufacturing process according to claim 8, and
a conveyor capable of moving a substrate on which a first layer is formed between at least one region of sulphurization annealing, and at least one region of selenization annealing.

19. Manufacturing process according to claim 10, wherein the formation of the homogeneous layer comprises:
depositing, by dry route or by liquid route, precursors chosen from metal precursors, sulphide precursors, and selenide precursors,
converting the deposited precursors so as to result in the homogeneous layer.

20. Arrangement according to claim 6, wherein the material from which the first layer is formed is composed of the compound having the following chemical formula Cu₂ZnSn(Se₍ₓ₎S₍₁₋ₓ₎)₄.
